(19) United States
(12) Patent Application Publication
(10) Pub. No.: US 2025/0305425 A1
(43) Pub. Date: Oct. 2, 2025

(54) PLAIN BEARING ARRANGEMENT FOR AN AIRCRAFT ENGINE AND AIRCRAFT ENGINE HAVING A PLAIN BEARING ARRANGEMENT

(71) Applicant: MTU Aero Engines AG, Muenchen (DE)

(72) Inventors: Joachim FALLER, Munich (DE); Mike MOSBACHER, Munich (DE)

(21) Appl. No.: 19/207,697

(22) Filed: May 14, 2025

(30) Foreign Application Priority Data
May 17, 2024 (DE) 102024113983.8

(51) Int. Cl. F01D 25/16; F01D 17/16

(52) U.S. Cl. CPC F01D 25/166; F01D 17/16; F05D 2220/323; F05D 2260/79; F05D 2300/224; F05D 2300/611

(57) ABSTRACT

A plain bearing arrangement (14), in particular for an aircraft engine, including a first component (10) and a second component (12), the first component (10) being slidingly mounted on the second component (12), and the first and/or second component (10, 12) having at least one tribological coating (18), the coating (18) being a single-layer amorphous carbon coating having an sp² content and an sp³ content, the sp³ content being between 50 at. % and 75 at. %, based on the total amount of substance of the coating (18). An aircraft engine having such a plain bearing arrangement (14) is also provided.

This claims priority to German Patent Application DE 102024113983.8, filed on May 17, 2024 which is hereby incorporated by reference herein.

The invention relates to a plain bearing arrangement and an aircraft engine having such a plain bearing arrangement.

### BACKGROUND

Aircraft engines and other gas turbines generally include a compressor for compressing air, a combustor for burning a hydrocarbon fuel in the presence of pressurized air, and a turbine for extracting energy from the resultant combustion gases. Aircraft engines have numerous plain bearing devices in which a first component is slidingly movably mounted on a second component. Plain bearings are generally tribological elements that support loads and have direct contact between two relatively movable components. The movement may be a linear sliding movement or a rotary sliding movement. In order to counteract the influence of high temperatures and vibrations, at least one of the components has at least one tribological coating made of an amorphous carbon material in the sliding area. Amorphous carbon materials do not have a regular crystalline structure, but are in an amorphous or non-crystalline state. Unlike crystalline carbon, which has an ordered lattice structure, amorphous carbon layers are disordered and have different structural properties. The amorphous carbon material coating serves to reduce friction and improves wear resistance.

U.S. Pat. No. 11,566,535 B1 describes a tribological coating for rotatable stator vanes, which is composed of a plurality layers of amorphous carbon materials with a hydrogen content of up to 30 atomic percent (at. %). This form of sliding bearing of the stator vanes is based on the fact that a third body in the form of a graphite-rich film is formed between the trunnion and the bushing during break-in. This film reduces the friction coefficients and thus the dissipated energy, which in turn reduces the wear on the trunnion and the bushing.

### SUMMARY OF THE INVENTION

In practice, however, this mechanism is often inhibited by the ambient conditions, which results in both severe abrasion of the bushings and wear of the trunnions. The wear on the trunnion and/or the bushings results in large excursions of the stator vanes and may possibly lead to contact with other components of the compressor. In addition, these multi-layer coatings are very complex to manufacture.

It is an object of the present invention to provide a plain bearing arrangement that is simple to manufacture and has improved sliding properties. Another object of the invention is to provide an aircraft engine having at least one such plain bearing arrangement.

The present invention provides a plain bearing arrangement (14) for an aircraft engine, comprising a variable stator vane (10) and a compressor casing component (12), [the variable stator vane (10)] being slidingly mounted on the compressor casing component (12), and the variable stator vane (10) and/or the compressor casing component (12) having at least one tribological coating (18), characterized in that the coating (18) is a single-layer amorphous carbon coating having an sp² content and an sp³ content, the sp³ content being between 50 at. % and 75 at. %, based on the total amount of substance of the coating (18). The present invention also provides an aircraft engine having at least one plain bearing arrangement described above.

Advantageous embodiments of the invention, including useful refinements thereof, are defined in the dependent claims. Advantageous embodiments of the plain bearing arrangement are to be considered as advantageous embodiments of the aircraft engine and vice versa.

A first aspect of the invention relates to a plain bearing arrangement for an aircraft engine, including a first component and a second component, the first component being a variable stator vane and the second component being a compressor casing component, the first component being slidingly mounted on the second component, and the first and/or second component having at least one tribological coating. In accordance with the invention, the coating is a single-layer amorphous carbon coating having an sp² content and an sp³ content, the sp³ content being between 50 at. % and 75 at. %, based on the entire coating. Thus, in comparison to known coatings, the coating according to the invention is not multi-layer, but single-layer, which facilitates the manufacture thereof. The inventive coating, which can also be referred to as “diamond-like carbon” layer (DLC layer), also has a high hardness and can be easily applied to metal surfaces. The initially high sp³ carbon content of the coating is then re-hybridized to sp² carbon, at least in the surface zone, by the friction between the components, i.e. by the tribological contact of the plain bearing arrangement, which automatically results in a substantial reduction of friction at the surface of the coating. Thus, the coating firstly acts as a wear protection layer and secondly provides a friction-reducing effect, as it protects the components in the sliding area from wear and nevertheless allows a sliding movement of the components relative to each other by forming a kind of carbon transfer film. In principle, the coating may be provided only on the first component or on the second component. It is also possible to provide the coating on both components.

An advantageous embodiment of the invention provides that a content of hydrogenated carbon is less than 10 at. %, in particular less than 1 at. %, and preferably 0 at. %, based on the total amount of substance of the coating. In other words, the coating according to the invention has a very low hydrogen content or is preferably free of hydrogen. Preferably, the coating is thus substantially or exclusively composed of sp³- and sp²-hybridized carbon. This ensures particularly high hardness and wear resistance without adversely affecting the tribological properties.

Further advantages are obtained when the sp³ content is between 55 at. % and 70 at. %, based on the total amount of substance of the coating. This makes it possible to achieve optimal wear resistance levels for different types of plain bearings, while at the same time providing excellent reduction of sliding friction.

In accordance with the invention, the first component and the second component are components of an adjustment system of a compressor of an aircraft engine, where, in particular, the first component is a variable stator vane and the second component is a compressor casing component. Since the thermal stresses occurring in the compressor area of aircraft engines are relatively low compared to the turbine area, the coating according to the invention consequently has a particularly long service life. In particular, if the first component is a variable stator vane and the second component is a compressor casing component, the coating of the inventive plain bearing arrangement ensures particularly low wear and at the same time good sliding properties, so that the functioning of the stator vane adjustment mechanism of the associated compressor can be ensured over a particularly long period of time. In this embodiment, the coating is preferably applied at least to the stator vane.

A further embodiment of the invention provides that the first component and the second component form a ball-and-socket joint. In this case, too, the advantageous properties of the coating of the plain bearing arrangement in terms of friction reduction and wear protection can be advantageously realized for an important structural element.

Another advantageous embodiment of the invention provides that the first component has at least one trunnion and the second component has at least one bushing, the trunnion of the first component being slidingly rotatably mounted in the bushing of the second component. A bushing generally has a (hollow) cylindrical shape and permits relative rotational movement of the trunnion by sliding. The bushing can also be referred to as a bearing bush or plain bearing bush. The second component may, for example, be a casing part having a bushing. In a simplest embodiment, the second component is a bushing.

Further advantages are obtained when at least one trunnion of the first component and/or at least one bushing of the second component have/has at least two spaced-apart coatings. In other words, the coating on the trunnion and/or in the bushing is not continuous over the entire sliding surface, so that there are uncoated surface areas. Preferably, two coatings are formed in respective end regions of the trunnion and/or the bushing. This can reduce the frictional resistance. In addition, radial forces acting on the trunnion can be compensated for more effectively since, even if the trunnion tilts within the bushing, it is ensured that contact between the trunnion and bushing and sliding of the trunnion in the bushing is only via coated surface areas. It is generally noted that in the context of the present disclosure, the terms “axial,” “radial” and “circumferential” refer to the axis of rotation of the trunnion, unless the context implicitly or explicitly indicates otherwise.

Further advantages are obtained when the coating has a layer thickness of between 500 nm and 2000 nm, in particular between 500 nm and 1500 nm. Such a layer thickness ensures optimum friction reduction and wear protection for most applications.

Another advantageous embodiment of the invention provides that the coating is applied by vapor deposition, preferably by physical vapor deposition (PVD), by sputtering, or by a combination thereof. Especially the use of PVD allows particularly precise control of the layer thickness and of the composition of the coating with regard to its sp²/sp³ contents at relatively low temperatures and ensures good adhesion of the coating to the component.

A second aspect of the invention relates to an aircraft engine having at least one plain bearing arrangement according to the first aspect of the invention. The resulting features and their advantages can be inferred from the descriptions of the first aspect of the invention. Preferably, the aircraft engine has a plurality of plain bearing arrangements as part of a stator vane adjustment system of a compressor. Each plain bearing arrangement includes a variable stator vane as a first component and two opposite bushings as second components, each bushing accommodating a respective end trunnion of the stator vane. The coating of the plain bearing arrangement according to the invention is preferably provided or formed at least on the trunnions of the stator vane(s). This enables simple and low-maintenance adjustment of the stator vanes without causing increased wear and associated large excursions of the stator vanes or possible contact with other compressor assemblies.

### BRIEF DESCRIPTION OF THE DRAWINGS

Further features and variations of the invention will be apparent from the claims, the figures, and the description of the figures. The features and feature combinations mentioned above in the description as well as those described and shown in the figures or shown in the figures alone may be used not only in the specified combinations, but also in other combinations without departing from the scope of the invention. Therefore, embodiments of the invention which are not explicitly shown and explained in the figures, but arise from and can be produced on the basis of the feature combinations described are also considered as encompassed and disclosed. Embodiments and feature combinations which do not have all of the features of an originally formulated independent claim should also be considered as disclosed. Moreover, embodiments and combinations of features which go beyond or differ from the combinations of features set forth in the back-references of the claims should also be considered as disclosed. In the drawings:

FIG. 1 is a schematic sectional view of a variable stator vane of a plain bearing arrangement according to the invention;

FIG. 2 a schematic sectional view of a bushing of the plain bearing arrangement according to the invention; and

FIG. 3 is a ternary diagram of amorphous carbon materials.

### DETAILED DESCRIPTION

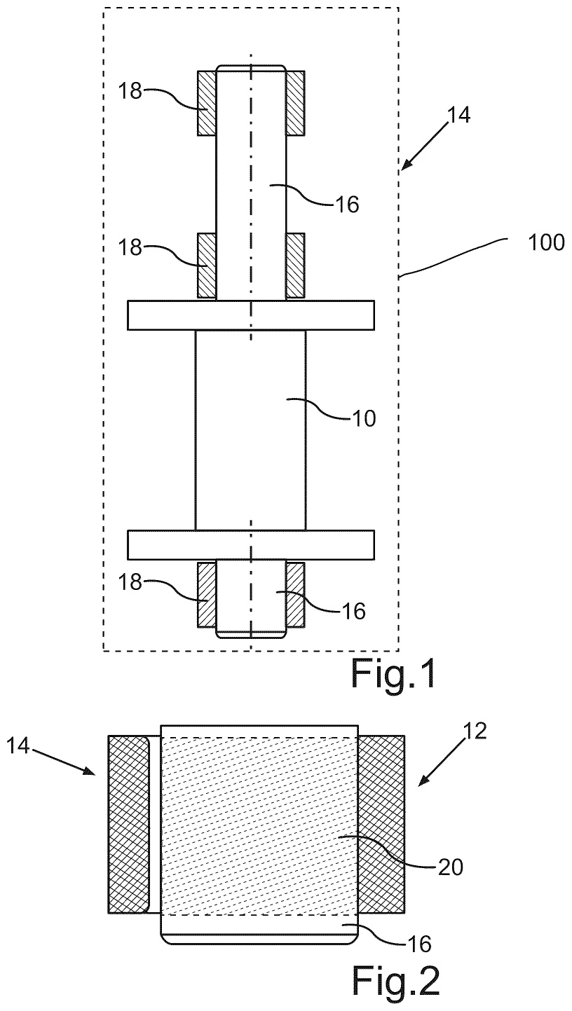

FIG. 1 shows, in schematic sectional view, a first component 10 in the form of a variable stator vane. Stator vane 10 and two bushings (FIG. 2) as second components 12 together form a plain bearing arrangement 14 according to the invention for a variable stator vane system of a compressor of an aircraft engine (shown-solely schematically as 100). Bushings 12 may be part of a compressor casing component. Stator vane 10 includes two opposite end trunnions 16, each provided with a tribological coating 18. Coating 18 is applied to the respective trunnions 16 as a single-layer amorphous carbon coating having an sp² content and an sp³ content, the sp³ content being between 50 at. % and 70 at. %, based on the total amount of substance of coating 18. Coating 18 is preferably formed by physical vapor deposition and has a layer thickness of between 500 nm and 2000 nm. The single-layer structure simplifies the manufacturing process as well as quality assurance and analysis significantly compared to conventional multi-layer systems made up of multiple amorphous gradient layers of amorphous C:H:Si:O.

It can be seen that a coating 18 is applied to the radially inner trunnion 16 and two spaced-apart coatings 18 are applied to the radially outer trunnion 16, each of the coatings 18 being formed completely therearound. In contrast to a complete coating of trunnion 16, the two spaced-apart coatings 18 in the respective end regions of the radially outer trunnion 16 make it possible to achieve reductions in friction and to particularly reliably compensate for radial forces acting on stator vane 10, which forces can lead to tilting of stator vane 10. The coatings 18 may be identical or different in terms of composition and layer thickness.

FIG. 2 shows, in schematic sectional view, one of the two bushings 12 of the inventive plain bearing arrangement 14, the bushing shown accommodating the radially inner trunnion 16 of the stator vane 10 shown in FIG. 1. The sliding bearing of stator vane 10 is based on the fact that a third sliding body 20 in the form of a graphite-rich film is formed on trunnion 16 during the break-in of plain bearing arrangement 14. This sliding body 20 reduces the friction coefficients and thus the dissipated energy, which in turn reduces the wear on trunnion 16 and bushings 12.

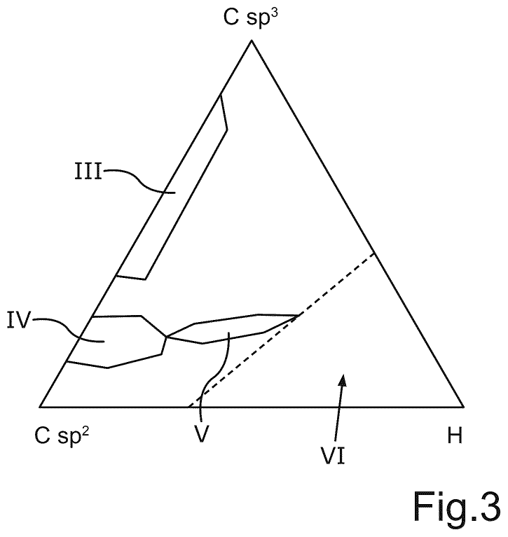

FIG. 3 shows a ternary diagram of amorphous carbon materials, where the vertices of the axes represent the three components: sp²-hybridized carbon (sp²-C), sp³-hybridized carbon (sp³-C), and hydrogen (H). Thus, the corners of the triangle represent the “pure” components, while the axes characterize binary mixtures of the respective components. Ternary mixtures of the three components lie within the triangle. Arrow III indicates a region of the coating 18 of the plain bearing arrangement 14 according to the invention. It can be seen that the coating 18 of the inventive plain bearing arrangement 14 consists predominantly of sp³-hybridized carbon, whose content is in particular between 50 at. % and 70 at. %. It can also be seen that coating 18 is at least substantially free of hydrogen.

In contrast, arrows IV and V identify coatings known from the prior art which have a significantly higher sp²-C content or H content. Finally, arrow VI indicates a region where generally no film formation and thus no coating is possible because of the high hydrogen content.

### LIST OF REFERENCE CHARACTERS

10 first component, stator vane
12 second component, bushing
14 plain bearing arrangement
16 trunnion
18 coating
20 sliding body
III region of the inventive mixture of components
IV, V non-inventive component mixtures
VI region without film formation

What is claimed is:

1-9. (canceled)

10. A plain bearing arrangement for an aircraft engine, the plain bearing arrangement comprising:
a compressor casing component;
a variable stator vane slidingly mounted on the compressor casing component, the variable stator vane or the compressor casing component having at least one tribological coating, the coating being a single-layer amorphous carbon coating having an sp² content and an sp³ content, the sp³ content being between 50 at. % and 75 at. %, based on a total amount of substance of the coating.

11. The plain bearing arrangement as recited in claim 10 wherein a content of hydrogenated carbon is less than 10 at. %.

12. The plain bearing arrangement as recited in claim 10 wherein a content of hydrogenated carbon is less than 1 at. %.

13. The plain bearing arrangement as recited in claim 10 wherein a content of hydrogenated carbon is 0 at. %, based on the total amount of substance of the coating.

14. The plain bearing arrangement as recited in claim 10 wherein the sp³ content is between 55 at. % and 70 at. %, based on the total amount of substance of the coating (18).

15. The plain bearing arrangement as recited in claim 10 wherein the variable stator vane and the compressor casing component form a ball-and-socket joint.

16. The plain bearing arrangement as recited in claim 10 wherein the variable stator vane has at least one trunnion and the compressor casing component has at least one bushing, the trunnion of the variable stator vane being slidingly rotatably mounted in the bushing of the compressor casing component.

17. The plain bearing arrangement as recited in claim 10 wherein at least one trunnion of the variable stator vane or at least one bushing of the compressor casing component have at least two spaced-apart coatings.

18. The plain bearing arrangement as recited in claim 10 wherein the coating has a layer thickness of between 500 nm and 2000 nm.

19. The plain bearing arrangement as recited in claim 10 wherein the coating has a layer thickness of between 500 nm and 1500 nm.

20. The plain bearing arrangement as recited in claim 10 wherein the coating is applied by vapor deposition, preferably by physical vapor deposition, by sputtering, or by a combination thereof.

21. The plain bearing arrangement as recited in claim 10 wherein the coating is applied by physical vapor deposition, by sputtering, or by a combination thereof.

22. An aircraft engine comprising at least one plain bearing arrangement as recited in claim 10.
